(19) United States
(12) Patent Application Publication
(10) Pub. No.: US 2024/0372578 A1
(43) Pub. Date: Nov. 7, 2024

(54) Electronic Devices Having Reconfigurable Power Amplifiers

(71) Applicant: Apple Inc., Cupertino, CA (US)

(72) Inventors: Mohammad B. Vahid Far, San Jose, CA (US); Danyom Berhane, San Jose, CA (US); Yilin Feng, San Jose, CA (US); Kevin Bastin, Fremont, CA (US)

(21) Appl. No.: 18/312,550

(22) Filed: May 4, 2023

(51) Int. Cl. H04B 1/401; H03F 1/56; H03F 3/24

(52) U.S. Cl. CPC H04B 1/401; H03F 1/56; H03F 3/245; H03F 2200/222

(57) ABSTRACT

An electronic device may include wireless circuitry with radios and a front end module coupled to an antenna. The module may include a multi-stage, multi-cell reconfigurable power amplifier and a radio-frequency coupler shared by the radios and different radio access technologies (RATs). One or more processors may adjust a number of active stages of the power amplifier, circuitry and bias conditions of the active stages, tunable capacitors on the module, adjustable impedance matching networks on the module and/or in the power amplifier, and/or the coupler using a digital interface to place the module in different operating modes corresponding to different RATs, power levels, modulation schemes, and/or frequencies. Adjusting the operating mode may allow the power amplifier to be reconfigured to meet performance requirements while maximizing performance, meeting regulatory requirements, and minimizing power. Sharing the power amplifier and the coupler across radios and RATs may produce space and power savings.

### FIELD

This disclosure relates generally to electronic devices and, more particularly, to electronic devices with wireless communications circuitry.

### BACKGROUND

Electronic devices are often provided with wireless communications capabilities. An electronic device with wireless communications capabilities has wireless communications circuitry with an antenna. A power amplifier provides signals to the antenna for transmission.

Over time, there is growing desire for wireless communications circuitry to cover a greater number of frequency bands and/or radio access technologies. However, it can be challenging to provide wireless circuitry with power amplifiers that cover different frequency bands and/or radio access technologies in a space and power-efficient manner and with satisfactory levels of radio-frequency performance.

### SUMMARY

An electronic device may include wireless circuitry for performing wireless communications. The wireless circuitry may include a set of radios, at least one antenna, baseband circuitry, and a radio-frequency front end (RFFE) module. The set of radios may be coupled to an antenna over a transmission line path having one or more transmission lines. The RFFE module may be disposed on the transmission line path. The baseband circuitry may generate a stream of data packets using a corresponding modulation coding scheme (MCS). The set of radios may generate radio-frequency signals that contain the data packets. The radio-frequency signals may be generated using different radio access technologies (RATs).

The RFFE module may include a multi-stage reconfigurable power amplifier disposed on a transmission line from the transmission line path and shared by the set of radios. The RFFE module may include a switch on the transmission line that couples the power amplifier to the antenna. The switch may have input ports each coupled to the output of a different respective stage of the power amplifier. Impedance matching networks and tunable capacitors may be coupled between the outputs of the stages of the power amplifier and the input ports of the switch. A radio-frequency coupler may be disposed on the transmission line between the switch and the antenna and may be shared by the set of radios. Additional impedance matching networks may be coupled to an input of the power amplifier and between the output terminal and the radio-frequency coupler.

One or more processors may adjust the power amplifier, the tunable capacitors, the impedance matching networks, the switch, and/or the radio-frequency coupler using a digital interface of the RFFE module to place the RFFE module in different selected operating modes on a packet-by-packet or group-of-packet by group-of-packet basis. Each operating mode may correspond to the RAT, modulation coding scheme (MCS), and/or frequency of the radio-frequency signals or packets being transmitted. Adjusting the operating mode of the RFFE module in this way may allow the power amplifier to be reconfigured to meet the performance requirements (e.g., EVM/SNR requirements) of the RAT and frequency being used while also maximizing wireless performance of the RFFE module, meeting regulatory requirements on radio-frequency power exposure, and minimizing power consumption. Sharing the power amplifier and the radio-frequency coupler between multiple RATs and radios may produce significant space and power savings in the device.

An aspect of the disclosure provides an electronic device. The electronic device can include a transmission line configured to convey a radio-frequency signal. The electronic device can include a switch disposed on the transmission line. The electronic device can include a power amplifier disposed on the transmission line and configured to amplify the radio-frequency signal. The power amplifier can include a first amplifier stage having an input and an output. The power amplifier can include a first signal path that couples the output of the first amplifier stage to a first input terminal of the switch. The power amplifier can include a second amplifier stage having an output coupled to the input of the first amplifier stage. The power amplifier can include a second signal path that couples the output of the first amplifier stage to a second input terminal of the switch around the first amplifier stage.

An aspect of the disclosure provides an electronic device. The electronic device can include an antenna. The electronic device can include a first radio configured to generate a first radio-frequency signal using a first radio access technology (RAT). The electronic device can include a second radio configured to generate a second radio-frequency signal using a second RAT different from the first RAT. The electronic device can include a substrate separate from the first radio and the second radio. The electronic device can include a transmission line on the substrate that communicably couples the first radio and the second radio to the antenna. The electronic device can include a power amplifier on the substrate and disposed on the transmission line, wherein the power amplifier has power amplifier stages, the power amplifier is configured to transmit the first radio-frequency signal using a set of the power amplifier stages, and the power amplifier is configured to transmit the second radio-frequency signal using a subset of the set of the power amplifier stages.

An aspect of the disclosure provides a method of operating wireless circuitry to transmit a radio-frequency signal. The method can include transmitting radio-frequency signals using one or more radios. The method can include amplifying the radio-frequency signals using a set of power amplifier stages coupled in series between the one or more radios and an antenna. The method can include adjusting, using one or more processors, a number of power amplifier stages in the set of power amplifier stages based on a radio access technology (RAT) of the radio-frequency signals.

### BRIEF DESCRIPTION OF THE DRAWINGS

FIG. 1 is a schematic diagram of an illustrative electronic device having wireless circuitry with a radio-frequency front end module in accordance with some embodiments.

FIG. 2 is a circuit diagram of an illustrative radio-frequency front end module in accordance with some embodiments.

FIG. 3 is a state diagram showing an example in which an illustrative radio-frequency front end module may be switched between three different power modes in accordance with some embodiments.

FIG. 4 is a table of illustrative operating modes for a radio-frequency front end module that are each associated with a different combination of power mode and frequency resources in accordance with some embodiments.

FIG. 5 is a circuit diagram showing how an illustrative radio-frequency front end module may be provided with a reconfigurable multi-stage power amplifier for transmitting signals in different operating modes in accordance with some embodiments.

FIG. 6 is a flow chart of illustrative operations that may be performed by a radio-frequency front end module to transmit radio-frequency signals in different operating modes for different sets of transmitted data packets in accordance with some embodiments.

### DETAILED DESCRIPTION

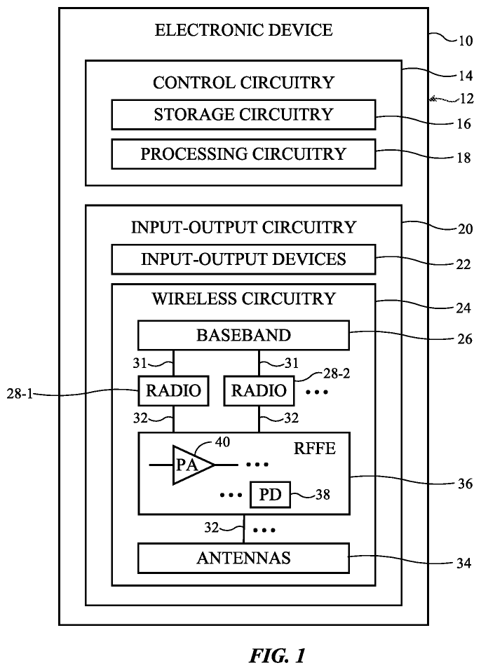

Electronic device 10 of FIG. 1 may be a computing device such as a laptop computer, a desktop computer, a computer monitor containing an embedded computer, a tablet computer, a cellular telephone, a media player, or other handheld or portable electronic device, a smaller device such as a wristwatch device, a pendant device, a headphone or earpiece device, a device embedded in eyeglasses or other equipment worn on a user's head, or other wearable or miniature device, a television, a computer display that does not contain an embedded computer, a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the schematic diagram FIG. 1, device 10 may include components located on or within an electronic device housing such as housing 12. Housing 12, which may sometimes be referred to as a case, may be formed of plastic, glass, ceramics, fiber composites, metal (e.g., stainless steel, aluminum, metal alloys, etc.), other suitable materials, or a combination of these materials. In some situations, part or all of housing 12 may be formed from dielectric or other low-conductivity material (e.g., glass, ceramic, plastic, sapphire, etc.). In other situations, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing communications protocols. Communications protocols that may be implemented using control circuitry 14 include internet protocols, wireless local area network (WLAN) protocols (e.g., IEEE 802.11 protocols-sometimes referred to as Wi-Fi®), protocols for other short-range wireless communications links such as the Bluetooth® protocol or other wireless personal area network (WPAN) protocols, IEEE 802.11ad protocols (e.g., ultra-wideband (UWB) protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), antenna diversity protocols, satellite navigation system protocols (e.g., global positioning system (GPS) protocols, global navigation satellite system (GLONASS) protocols, etc.), antenna-based spatial ranging protocols, optical communications protocols, or any other desired communications protocols. Each communications protocol may be associated with a corresponding radio access technology (RAT) that specifies the physical connection methodology used in implementing the protocol (e.g., a WLAN RAT, a WPAN RAT, a cellular telephone RAT such as a 4G RAT, 5G RAT, 3G RAT, 6G RAT, etc., a UWB RAT, etc.).

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays, light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include wireless circuitry 24 to support wireless communications. Wireless circuitry 24 (sometimes referred to herein as wireless communications circuitry 24) may include baseband circuitry such as baseband circuitry 26 (e.g., one or more baseband processors and/or other circuitry that operates at baseband), radio-frequency (RF) transceiver circuitry such as one or more radios 28, radio-frequency front end (RFFE) circuitry such as RFFE circuitry 36, and one or more antennas 34. If desired, wireless circuitry 24 may include multiple antennas 34 that are arranged into a phased antenna array (sometimes referred to as a phased array antenna) that conveys radio-frequency signals within a corresponding signal beam that can be steered in different directions.

Baseband circuitry 26 may be coupled to radio(s) 28 over one or more baseband signal paths 31. Baseband circuitry 26 may include, for example, modulators (encoders) and demodulators (decoders) that operate on baseband signals. Each radio 28 may be coupled to one or more antennas 34 over one or more radio-frequency transmission line paths 32 (sometimes referred to herein as radio-frequency signal paths 32). RFFE circuitry 36 may be disposed on radio-frequency transmission line path(s) 32 between radio 28 and antennas 34.

If desired, wireless circuitry 24 may include a set of two or more radios 28 (e.g., at least a first radio 28-1, a second radio 28-2, etc.). Each radio 28 may include transceiver circuitry (e.g., a transmitter and/or receiver) that transmits and/or receives radio-frequency signals. Radio 28 may sometimes also be referred to herein as transceiver circuitry 28 or transceiver 28. Each radio 28 may convey radio-frequency signals using a corresponding RAT. If desired, different radios 28 may convey radio-frequency signals using different RATs (e.g., a first radio 28 may convey cellular telephone signals, a second radio 28 may convey Wi-Fi signals, etc.). If desired, the same radio 28 may convey radio-frequency signals using two or more RATs (e.g., a given radio 28 may convey both Wi-Fi and Bluetooth signals, a given radio 28 may convey both 4G cellular telephone signals and 5G cellular telephone signals, a given radio 28 may both convey cellular telephone signals and receive satellite navigation signals, etc.).

Each radio 28 may be coupled to the same antenna 34 over different radio-frequency transmission line paths 32, two or more radios 28 may be coupled to the same antenna 34 over the same radio-frequency transmission line path, a given radio 28 may be coupled to different antennas over different radio-frequency transmission line paths, etc. In general, any desired number of one or more radio-frequency transmission line paths 32 may be used to couple one or more radios 28 to one or more antennas 34 and, if desired, two or more radios 28 may be coupled to the same antenna(s) 34 over the same radio-frequency transmission line path(s) 32. Any desired number of two or more of the radios 28 in wireless circuitry 24 may be coupled to the same RFFE circuitry 36 (e.g., RFFE circuitry 36 disposed on the one or more radio-frequency transmission line paths 32 coupling the two or more radios 28 to one or more antennas 34) or different respective radios 28 may be coupled to different respective RFFE circuitry 36. In general, wireless circuitry 24 may include any desired number of radios 28, any desired number of radio-frequency transmission line paths 32, and desired number of RFFE modules, and any desired number of antennas 34.

Radio-frequency transmission line path(s) 32 may be coupled to antenna feeds on one or more antennas 34. Each antenna feed may, for example, include a positive antenna feed terminal and a ground antenna feed terminal. Each radio-frequency transmission line path 32 may have a positive transmission line signal path that is coupled to one or more positive antenna feed terminals and may have a ground transmission line signal path that is coupled to the ground antenna feed terminal. This example is merely illustrative and, in general, antennas 34 may be fed using any desired antenna feeding scheme.

Radio-frequency transmission line paths 32 may include transmission lines that are used to route radio-frequency antenna signals within device 10. Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Radio-frequency transmission line paths 32 may also include radio-frequency connectors that couple multiple transmission lines together. Transmission lines in device 10 such as transmission lines in radio-frequency transmission line path 32 may be integrated into rigid and/or flexible printed circuit boards. In some implementations, radio-frequency transmission line paths such as radio-frequency transmission line path 32 may also include transmission line conductors integrated within multilayer laminated structures (e.g., layers of a conductive material such as copper and a dielectric material such as a resin that are laminated together without intervening adhesive). The multilayer laminated structures may, if desired, be folded or bent in multiple dimensions (e.g., two or three dimensions) and may maintain a bent or folded shape after bending (e.g., the multilayer laminated structures may be folded into a particular three-dimensional shape to route around other device components and may be rigid enough to hold its shape after folding without being held in place by stiffeners or other structures). All of the multiple layers of the laminated structures may be batch laminated together (e.g., in a single pressing process) without adhesive (e.g., as opposed to performing multiple pressing processes to laminate multiple layers together with adhesive).

In performing wireless transmission, baseband circuitry 26 may provide baseband signals to a radio 28 over baseband signal path(s) 31. Radio 28 (e.g., one or more transmitters in radio 28) may include circuitry for converting the baseband signals received from baseband circuitry 26 into corresponding radio-frequency signals. For example, radio 28 may include mixer circuitry for up-converting the baseband signals to radio frequencies prior to transmission over antennas 34. Radio 28 may also include digital to analog converter (DAC) and/or analog to digital converter (ADC) circuitry for converting signals between digital and analog domains. Radio 28 may transmit the radio-frequency signals over antennas 34 via radio-frequency transmission line path 32 and RFFE circuitry 36. Antennas 34 may transmit the radio-frequency signals to external wireless equipment (e.g., a wireless access point, a wireless base station, another device 10, an accessory device, a peripheral device, a head-mounted device, a communications satellite, etc.) by radiating the radio-frequency signals into free space.

In performing wireless reception, antennas 34 may receive radio-frequency signals from the external wireless equipment. The received radio-frequency signals may be conveyed to a corresponding radio 28 via radio-frequency transmission line path 32 and RFFE circuitry 36. Radio 28 may include circuitry for converting the received radio-frequency signals into corresponding baseband signals. For example, radio 28 may include one or more receivers having mixer circuitry for down-converting the received radio-frequency signals to baseband frequencies prior to conveying the baseband signals to baseband circuitry 26.

RFFE circuitry 36 may include radio-frequency front end components that operate on radio-frequency signals conveyed over the corresponding radio-frequency transmission line path 32. In implementations that are described herein as an example, the radio-frequency front end components of RFFE circuitry 36 may be disposed within a corresponding RFFE module (sometimes referred to as an RF module (RFM)). RFFE circuitry 36 may therefore sometimes also be referred to herein as RFFE module 36, RFM 36, or radio-frequency front end 36.

The radio-frequency front end components of RFFE module 36 may be mounted to a common (shared) substrate such as a printed circuit board substrate (e.g., a rigid or flexible printed circuit board). If desired, RFFE module 36 may be a multi-chip module (MCM). The radio-frequency front end components of RFFE module 36 may be formed from one or more integrated circuits and/or surface mount components (e.g., surface mount technology (SMT) components) mounted (e.g., soldered) to the common substrate, may be printed onto the common substrate, may be embedded within the common substrate, etc.

The radio-frequency front end components in RFFE module 36 may include switching circuitry (e.g., one or more radio-frequency switches), radio-frequency filter circuitry (e.g., low pass filters, high pass filters, notch filters, band pass filters, multiplexing circuitry, duplexer circuitry, diplexer circuitry, triplexer circuitry, etc.), impedance matching circuitry (e.g., circuitry that helps to match the impedance of antennas 34 to the impedance of radio-frequency transmission line path 32, circuitry that helps to match the impedance of some components in RFFE module 36 to other components in RFFE module 36, etc.), antenna tuning circuitry (e.g., networks of capacitors, resistors, inductors, and/or switches that adjust the frequency response of antennas 34), radio-frequency amplifier circuitry (e.g., power amplifier (PA) circuitry such as one or more power amplifiers 40 and/or low-noise amplifier circuitry), radio-frequency coupler circuitry, power detector (PD) circuitry such as one or more power detectors 38, charge pump circuitry, power management circuitry, low dropout (LDO) regulator circuitry, digital control and interface circuitry, and/or any other desired circuitry that operates on the radio-frequency signals transmitted and/or received by the antenna(s) 34 coupled to the RFFE module over the corresponding radio-frequency transmission line path 32.

If desired, radio-frequency components for the RFFE circuitry associated with a given radio 28 and/or a given antenna 34 may be distributed across multiple RFFE modules 36 disposed on the radio-frequency transmission line path 32 coupled to that radio and/or antenna. For example, the RFFE modules 36 in wireless circuitry 24 may include one or more power amplifier modules having one or more power amplifiers 40 and may include other modules having other radio-frequency components from the RFFE circuitry.

While control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, baseband circuitry 26 and/or portions of radio(s) 28 (e.g., a host processor on radio(s) 28) may form a part of control circuitry 14.

Wireless circuitry 24 may transmit and/or receive wireless signals within corresponding frequency bands of the electromagnetic spectrum (sometimes referred to herein as communications bands or simply as “bands”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, etc.), other centimeter or millimeter wave frequency bands between 10-100 GHz, near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, communications bands under the family of 3GPP wireless communications standards, communications bands under the IEEE 802.XX family of standards, and/or any other desired frequency bands of interest. Each radio 28 may transmit and/or receive radio-frequency signals in one or more of these frequency bands.

Antennas 34 may be formed using any desired antenna structures. For example, antennas 34 may include antennas with resonating elements that are formed from loop antenna structures, patch antenna structures, inverted-F antenna structures, slot antenna structures, planar inverted-F antenna structures, helical antenna structures, monopole antennas, dipoles, hybrids of these designs, etc. Parasitic elements may be included in antennas 34 to adjust antenna performance.

Filter circuitry, switching circuitry, impedance matching circuitry, and other circuitry may be interposed within radio-frequency transmission line path 32, may be incorporated into RFFE module 36, and/or may be incorporated into antennas 34 (e.g., to support antenna tuning, to support operation in desired frequency bands, etc.). These components, sometimes referred to herein as antenna tuning components, may be adjusted (e.g., using control circuitry 14) to adjust the frequency response and wireless performance of antennas 34 over time.

In general, each radio 28 may cover (handle) any suitable communications (frequency) bands of interest. The radio may convey radio-frequency signals using antennas 34 (e.g., antennas 34 may convey the radio-frequency signals for the transceiver circuitry). The term “convey radio-frequency signals” as used herein means the transmission and/or reception of the radio-frequency signals (e.g., for performing unidirectional and/or bidirectional wireless communications with external wireless communications equipment). Antennas 34 may transmit the radio-frequency signals by radiating the radio-frequency signals into free space (or to free space through intervening device structures such as a dielectric cover layer). Antennas 34 may additionally or alternatively receive the radio-frequency signals from free space (e.g., through intervening devices structures such as a dielectric cover layer). The transmission and reception of radio-frequency signals by antennas 34 each involve the excitation or resonance of antenna currents on an antenna resonating element in the antenna by the radio-frequency signals within the frequency band(s) of operation of the antennas.

In example where multiple antennas 34 are arranged in a phased antenna array, each antenna 34 may form a respective antenna element of the phased antenna array. Conveying radio-frequency signals using the phased antenna array may allow for greater peak signal gain relative to scenarios where individual antennas 34 are used to convey radio-frequency signals. In satellite navigation system links, cellular telephone links, and other long-range links, radio-frequency signals are typically used to convey data over thousands of feet or miles. In Wi-Fi® and Bluetooth® links at 2.4 and 5 GHz and other short-range wireless links, radio-frequency signals are typically used to convey data over tens or hundreds of feet. In scenarios where millimeter or centimeter wave frequencies are used to convey radio-frequency signals, a phased antenna array may convey radio-frequency signals over short distances that travel over a line-of-sight path. To enhance signal reception for millimeter and centimeter wave communications, the phased antenna array may convey radio-frequency signals using beam steering techniques (e.g., schemes in which antenna signal phase and/or magnitude for each antenna in an array are adjusted to perform beam steering).

For example, each antenna 34 in the phased antenna array may be coupled to a corresponding phase and magnitude controller. The phase and magnitude controllers may adjust the relative phases and/or magnitudes of the radio-frequency signals that are conveyed by each of the antennas 34 in the phased antenna array. The wireless signals that are transmitted or received by the phased antenna array in a particular direction may collectively form a corresponding signal beam. The signal beam may exhibit a peak gain that is oriented in a particular pointing direction at a corresponding pointing angle (e.g., based on constructive and destructive interference from the combination of signals from each antenna in the phased antenna array). Control circuitry 14 may adjust the phase and magnitude controllers to change the direction of the signal beam over time (e.g., to allow device 10 to continue to communicate with external equipment even if the external equipment moves relative to device 10 over time). This example is merely illustrative and, in general, antennas 34 need not be arranged in a phased antenna array.

A given RFFE module 36 may be coupled to several radios 28, antennas 34, and/or other radio sub-systems, where each radio may cover a different respective RAT. In practice, power amplifiers are among the most power-hungry components in device 10. Power consumption by the power amplifiers can cause the power amplifiers to define the thermal limitations of the RFFE modules. As such, efficiency of the power amplifiers is important for meeting thermal and battery usage requirements for device 10. At the same time, power amplifier operation should be well-controlled to meet all applicable regulatory requirements (e.g., requirements on radio-frequency exposure such as specific absorption rate (SAR) and/or maximum permissible exposure (MPE) requirements) and to satisfy coexistence requirements with other wireless technologies implemented by device 10 and/or nearby devices. In other words, the power amplifiers may operate with tight controls on emission, power delivery, calibration, signal waveform, modulation, channel bandwidth, and/or other requirements. These controls and requirements may vary across RATS and may be particularly tight for some RATs such as Wi-Fi 6E. In addition, the power amplifiers need to exhibit consistent and satisfactory performance across different antenna loading conditions (e.g., as the voltage standing wave ratio (VSWR) of the corresponding antenna(s) change due to impedance loading from nearby external objects in the environment such as body parts, furniture, etc.).

To mitigate these issues, in some scenarios, a given RFFE module 36 may include multiple different power amplifiers that are each dedicated to a given radio, RAT, and/or frequency band. This may help to allow the circuitry and the configuration of each power amplifier to be optimized for its corresponding combination of radio, RAT, and/or frequency band (e.g., to meet the control requirements associated with its RAT and/or frequency band). As an example, wireless circuitry 24 may include an RFFE module 36 having a first power amplifier dedicated to transmitting WLAN signals for a WLAN radio 28, a second power amplifier dedicated to transmitting Bluetooth signals for a Bluetooth radio 28, a third power amplifier dedicated to transmitting UWB signals for a UWB radio 28, etc. (e.g., because the WLAN, Bluetooth, and UWB RATs each have different signal-to-noise ratio (SNR), error vector magnitude (EVM), or modulation constellation requirements that are met through by circuitry and configuration of each power amplifier).

However, providing different dedicated power amplifiers for each combination of RAT. radio, and frequency resources may cause the power amplifiers to consume an excessive amount chip area in device 10 (where space is at a premium), and can lead to excessive power consumption and heat generation in device 10. In addition, each power amplifier may require a different dedicated power detector 38 (and a corresponding radio-frequency coupler), which can also consume an excessive amount of chip area in device 10. Power detector 38 may, for example, be used to detect power levels of the signals transmitted by the corresponding power amplifier, to perform closed loop transmit power level adjustments (e.g., to increase the output power of the corresponding power amplifier when the measured transmit power level is lower than expected, to reduce the output power when the measured transmit power level is higher than expected, to reduce transmit power level to meet regulatory requirements, etc.), to measure the impedance of the corresponding antenna 34 (e.g., by measuring transmitted/forward signals and reverse/reflected signals, complex scattering parameters, VSWR, etc.), etc.

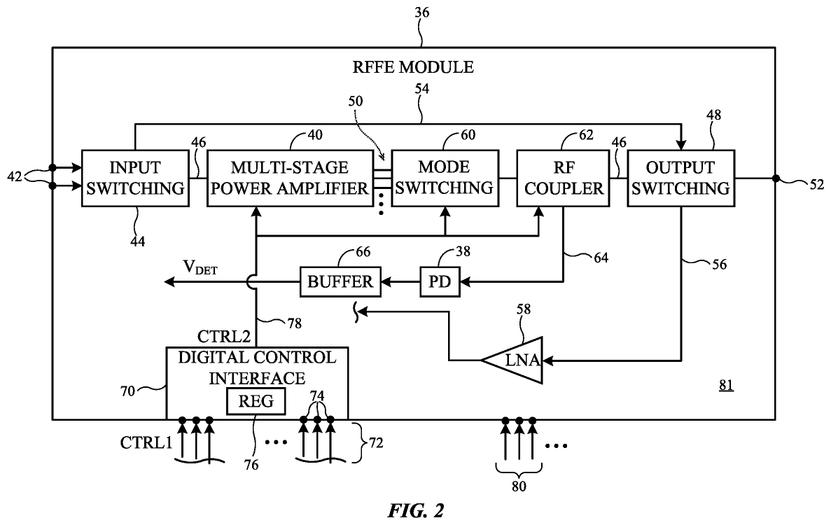

To mitigate these issues while consuming as little space and as little power in device 10 as possible, a given RFFE module 36 may include a reconfigurable multi-stage power amplifier 40 that is used to cover multiple RATs for multiple radios and/or multiple combinations of frequency resources. FIG. 2 is a circuit diagram of an RFFE module 36 having one such reconfigurable multi-stage power amplifier 40.

As shown in FIG. 2, RFFE module 36 may include input switching circuitry 44, power amplifier 40 (e.g., a multi-stage, multi-cell reconfigurable power amplifier), mode switching circuitry 60, one or more radio-frequency couplers such as RF coupler 62, output switching circuitry 48, power detector 38, buffer circuitry such as buffer 66, and control interface circuitry such as digital control interface 70 on (e.g., mounted to, printed on, and/or integrated within) a module substrate such as substrate 81 (e.g., a printed circuit board, a package substrate, a semiconductor substrate etc.). Radios 28 may be separate from (e.g., are not mounted to) substrate 81.

RFFE module 36 may have radio-frequency signal ports such as signal ports 42 and 52. Signal ports 42 may be coupled to one or more radios 28 (FIG. 1). If desired, different signal ports 42 may be coupled to different respective radios 28 and/or to different respective ports of the same radio 28. Each signal port 42 may receive radio-frequency signals from the coupled radio(s) 28 using different respective frequency resources (e.g., different frequency bands, different RATs, etc.).

Signal port 52 may be coupled to one or more corresponding antennas 34 (FIG. 1). Input switching circuitry 44 may have inputs coupled to signal ports 42. Output switching circuitry 48 may have an output coupled to signal port 52. The output of input switching circuitry 44 may be coupled to the input of output switching circuitry 48 over a transmit signal (data) path such as transmit path 46. Input switching circuitry 44 may include one or more radio-frequency switches. Output switching circuitry 48 may include one or more radio-frequency switches. Signal ports 42 and 52, input switching circuitry 44, output switching circuitry 48, and transmit path 46 may form part of the corresponding radio-frequency transmission line path 32 coupled to the antenna(s) 34 coupled to signal port 52 (e.g., part of a radio-frequency transmission line in radio-frequency transmission line path 32 that is disposed on RFFE module 36).

Power amplifier 40, mode switching circuitry 60, and RF coupler 62 may be disposed on transmit path 46. The output of input switching circuitry 44 may be coupled to the input of power amplifier 40. The output of power amplifier 40 may be coupled to the input of mode switching circuitry 60 (e.g., over a set of two or more signal paths 50 in transmit path 46). The output of mode switching circuitry 60 may be coupled to the input of output switching circuitry 48. RF coupler 62 may be disposed on transmit path 46 between mode switching circuitry 60 and output switching circuitry 48. If desired, RFFE module 36 may have a bypass path 54 that couples the output of input switching circuitry 44 to the input of output switching circuitry 48 around power amplifier 40, mode switching circuitry 60, and RF coupler 62. Input switching circuitry 44 and output switching circuitry 48 may include bypass switches that selectively activate transmit path 46 or bypass path 54 for the transmission of radio-frequency signals from signal port(s) 42 to signal port 52.

If desired, RFFE module 36 may also be used for the reception of radio-frequency signals from signal port 52. As such, RFFE module 36 may include a low noise amplifier (LNA) such as LNA 58 coupled to output switching circuitry 48 over receive path 56. While illustrated as a single LNA on receive path 56 for the sake of clarity, the LNA may be a multi-mode LNA with multiple adjustable bias settings and/or may be bypassable if desired. Output switching circuitry 48 may include a transmit/receive switch and/or filter circuitry that selectively route transmit signals from transmit path 46 to signal port 52 and receive signals from signal port 52 to LNA 58. The output of LNA 58 may be coupled to a receiver in a corresponding radio 28 (e.g., via an additional port of RFFE module 36 that is not shown in FIG. 2 for the sake of clarity).

The input of power detector 38 may be coupled to RF coupler 62 over feedback path 64. The input of buffer 66 may be coupled to the output of power detector 38. The output of buffer 66 to a feedback receiver in a corresponding radio 28 or control circuitry 14 (e.g., via an additional port of RFFE module 36 that is not shown in FIG. 2 for the sake of clarity).

RFFE module 36 may include a set of power supply input ports 80. Each power supply input port 80 may be coupled to a respective power supply line. Each power supply line may convey a respective power supply voltage from power management circuitry and/or a battery in device 10. RFFE module 36 may also include control ports (input terminals) 74. Control ports 74 may receive control signals CTRL1 from other control circuitry in device 10 (e.g., portions of control circuitry 14 of FIG. 1, portions of baseband circuitry 26 of FIG. 1, a system-on-chip (SoC), etc.) over control paths 72 external to RFFE module 36 (sometimes referred to herein as external control paths 72).

In some implementations that are described herein as an example, control signals CTRL1 include digital control signals. Digital control interface 70 may serve as an interface between control paths 72 and control paths 78 on RFFE module 36. Digital control interface 70 may convert the digital control signals received over control ports 74 into control signals CTRL2. Control signals CTRL2 may be distributed to the components of RFFE module 36 (sometimes referred to herein as controlled components) over control paths 78 internal to RFFE module 36 (sometimes referred to herein as internal control paths 78). Control signals CTRL2 may include digital control signals and/or any other desired control signals in a format that is used to control, adjust, configure, or set the components on RFFE module 36.

Digital control interface 70 may, for example, convert different digital signal values of the control signals CTRL1 received over control ports 74 into corresponding values of control signals CTRL2, which are then used to configure or adjust the operation of the controlled components of RFFE module 36. Digital control interface 70 may, for example, use entries stored on one or more registers such as register 76 to map values of the received control signals CTRL1 to corresponding values of control signals CTRL2. Digital control interface 70 may, for example, transmit at least some of control signals CTRL2 to power amplifier 40, mode switching circuitry 60, and RF coupler 62 over control paths 78. Control signals CTRL2 may be used to adjust the operation of power amplifier 40, mode switching circuitry 60, and RF coupler 62 for use in transmitting radio-frequency signals over transmit path 46.

While RFFE module 36 may include other control paths coupled between digital control interface 70 and other components on RFFE module 36, these control paths are not shown in FIG. 2 for the sake of clarity. If desired, some of the control ports 74 of RFFE module 36 may include serial communications ports (e.g., for serial interfaces such as a Mobile Industry Processor Interface RF Front End (MIPI RFFE) interfaces, Universal Asynchronous Receiver-Transmitter (UART) interfaces, System Power Management Interfaces (SPMI), Inter-Integrated-Circuit (I2C) interfaces, etc.), input-output communications ports such as General Purpose Input-Output (GPIO) communications ports, etc. If desired, RFFE module 36 may include additional signal ports 52 coupled to additional antennas 34, additional transmit paths 46, additional receive paths 56, and/or other circuitry.

During wireless signal reception, a radio-frequency signal may be received by the antenna(s) 34 coupled to signal port 52 and may be passed to RFFE module 36 over signal port 52. Output switching circuitry 48 may route the received radio-frequency signal to LNA 58. LNA 58 may amplify the received radio-frequency signal and may pass the amplified radio-frequency signal to a receiver in a corresponding radio 28.

During wireless signal transmission, radio-frequency signals may be received from one or more radios 28 over one or more signal ports 42. Input switching circuitry 44 may, if desired, include an input switch that selectively couples one of signal ports 42 to a bypass switch in input switching circuitry 44. The input switch may route a radio-frequency signal from one of ports 42 to the bypass switch. The bypass switch may selectively couple the input switch to bypass path 54 or transmit path 46. The bypass switch may route the radio-frequency signal to output switching circuitry 48 over transmit path 46 to amplify the radio-frequency signal using power amplifier 40 or may route the radio-frequency signal to output switching circuitry 48 over bypass path 54 when no amplification is needed.

Power amplifier 40 may amplify the radio-frequency signal received from input switching circuitry 44. Power amplifier 40 may include multiple power amplifier stages coupled in series along transmit path 46. Each signal path 50 may couple the output of a respective stage in power amplifier 40 to the input of mode switching circuitry 60. Mode switching circuitry 60 may selectively activate one or more of the stages in power amplifier 40 at a given time (e.g., to change the amount of amplification (gain) imparted to the transmitted radio-frequency signal by power amplifier 40). The activated stages of power amplifier 40 may amplify the transmitted radio-frequency signal (e.g., while bypassing the other (inactive) stages of power amplifier 40). The last stage in the activated stages of power amplifier 40 may pass the amplified radio-frequency signal to RF coupler 62 through the corresponding signal path 50 and mode switching circuitry 60.

RF coupler 62 may pass the radio-frequency signal amplified by power amplifier 40 to output switching circuitry 48. Output switching circuitry 48 may pass the radio-frequency signal to signal port 52 for transmission by the corresponding antenna(s) 34. RF coupler 62 may include a directional coupler, a switch coupler, a reflectometer, or any other desired radio-frequency coupler. RF coupler 62 may couple some of the transmitted radio-frequency signal (e.g., in a forward direction from power amplifier 40 towards signal port 52) and/or a reflected portion of the transmitted radio-frequency signal (e.g., in a reverse direction, as reflected off signal port 52 or the corresponding antenna(s) 34 back towards power amplifier 40 due to an impedance mismatch between the radio-frequency transmission line path and the antenna(s)) off of transmit path 46 and onto feedback path 64. If desired, there may be multiple RF couplers 62 disposed on transmit path 46.

Power detector 38 may measure or generate a signal (e.g., a voltage V_{DET}, a current I_{DET}, or a power P_{DET}) from the radio-frequency signal coupled off of transmit path 46 by RF coupler 62 (e.g., power detector 38 may convert a radio-frequency voltage waveform into a DC voltage). The signal (e.g., voltage V_{DET}) may be stored at buffer 66 and then passed to a feedback receiver on RFFE module 36, on a corresponding radio 28, or elsewhere, or to control circuitry 14 (FIG. 1). Control circuitry 14 may process the voltage and/or power measured by power detector 38 to measure (e.g., estimate, determine, identify, compute, calculate, generate, sense, etc.) the signal at RF coupler 62 (e.g., for measuring antenna impedance, performing closed-loop power control for power amplifier 40, etc.).

In this way, the same power amplifier 40 and radio-frequency coupler 62 may be shared across each of the radios 28, the corresponding RATs, and the frequency resources of the radios 28 coupled to signal ports 42. This may consume significantly less area and power than in implementations where different dedicated power amplifiers are used for different radios, RATs, and frequency resources. Given the different control requirements for each RAT, radio, and/or the corresponding frequency resources, RFFE module 36 may be switchable between different operating modes (sometimes referred to herein as operating states) for each combination of RAT, radio, and/or frequency resources that is used to transmit the radio-frequency signal over transmit path 46. Each operating mode may involve corresponding settings for power amplifier 40, mode switching circuitry 60, and/or RF coupler 62 that are optimized for the corresponding combination of RAT, radio, and frequency resources.

RFFE module 36 may receive a control signal CTRL1 that identifies the operating mode to use at any given time. The operating mode to use at a given time may be selected by control circuitry 14 (FIG. 1) based on any desired criteria. RFFE module 36 may generate control signals CTRL2 based on the received control signal CTRL1. Control signals CTRL2 may be used to configure the components of RFFE module 36 to enter the operating mode identified by control signal CTRL1. For example, internal control paths 78 may pass control signals CTRL2 to power amplifier 40, mode switching circuitry 60, and RF coupler 62. Control signals CTRL2 may adjust or reconfigure the settings of power amplifier 40, mode switching circuitry 60, and RF coupler 62 to place RFFE module 36 into the operating mode identified by control signal CTRL1.

While placed in the operating mode identified by control signal CTRL1, RFFE module 36 may transmit the radio-frequency signal received over signal port(s) 42 to signal port 52. The settings of power amplifier 40, mode switching circuitry 60, and RF coupler 62 may optimize the radio-frequency performance of RFFE module 36 in transmitting the radio-frequency signal while meeting the performance requirements associated with the RAT, radio, and/or frequency of the received radio-frequency signal (e.g., while also meeting regulatory requirements and wireless performance requirements and minimizing power consumption). As the combination of RAT, radio, and/or frequency of the received radio-frequency signal changes over time, the control circuitry may update control signals CTRL1 to reconfigure RFFE module 36 to transmit the radio-frequency signals in different operating modes as needed.

If desired, the control circuitry may use control signal CTRL1 to dynamically update the operating mode of RFFE module 36 on a per-packet basis (e.g., for each packet in the radio-frequency signal transmitted by RFFE module 36) or on a per-group-of-packets basis (e.g., for each set of multiple packets in the radio-frequency signals transmitted by RFFE module 36). This may ensure that RFFE module 36 continues to optimize wireless performance while meeting all applicable regulatory and technology-related performance requirements and while minimizing power consumption in real time even as the RAT and/or frequency of the transmitted radio-frequency signals changes between packets.

Each operating mode of RFFE module 36 may have an associated power mode related to the number of stages in power amplifier 40 that are active and thus the amount of power consumed by RFFE module 36 while in that operating mode. Each operating mode may be given by a different respective combination of power mode and frequency resources (e.g., frequency band) used for signal transmission. The control circuitry may use control signal CTRL1 to change the power mode of RFFE module 36 over time, which also changes the operating mode of RFFE module 36.

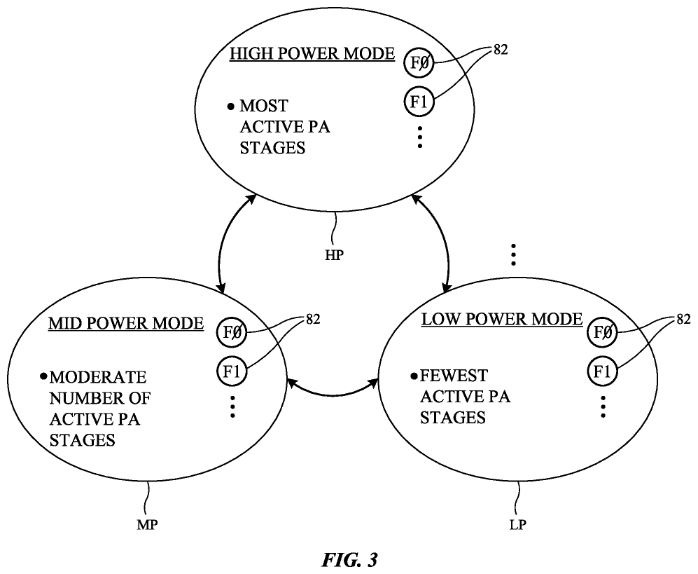

FIG. 3 is a state diagram showing how RFFE module 36 may be switched between three power modes. This is illustrative and, more generally, RFFE module 36 may be switched between two power modes or more than three power modes (e.g., multiple mid power modes, a high power mode, a low power mode, etc.). As shown in FIG. 3, RFFE module 36 may be placed in a high power mode HP, a low power LP, or a mid power mode MP. In high power mode HP, power amplifier 40 has more active stages and consumes more power than when in mid power mode MP. In mid power mode MP, power amplifier 40 has more active stages and consumes more power than when in low power mode LP. All or fewer than all of the stages of power amplifier 40 may be active in high power mode HP. One, more than one, or none of the stages of power amplifier 40 may be active in low power mode LP. Bypass path 54 may be used to transmit the radio-frequency signal when zero stages of power amplifier 40 are active if desired.

The active stages in power amplifier 40 (sometimes referred to herein as enabled stages) may be coupled onto transmit path 46 (FIG. 2) by mode switching circuitry 60 and may amplify the transmit signals on transmit path 46. The non-active stages of power amplifier 40 (sometimes referred to herein as inactive stages or disabled stages) may be decoupled from transmit path 46 by mode switching circuitry 60 such that the radio-frequency signal does not pass through the non-active stages. Control circuitry 14 may adjust control signal CTRL1 to switch RFFE module 36 between power modes HP, LP, and MP. While RFFE module 36 is sometimes referred to herein as being in power modes HP, LP, or MP, power amplifier 40 may sometimes also be referred to herein as being in power modes HP, LP, or MP. The example of FIG. 3 is illustrative and non-limiting. If desired, RFFE module 36 may be switched between two power modes or more than three power modes.

In each power mode, RFFE module 36 may also be configured to transmit the radio-frequency signal using different frequency resources F such as different frequency bands or sub-bands (e.g., frequency resources F0, F1, etc.) and/or with different modulation settings (e.g., modulation rates, modulation coding scheme rates, etc.). Frequency resources F may also correspond to a particular RAT and/or radio 28 (e.g., different RATs or radios may use different frequency resources). Different power modes may be associated with different frequency resources or RATs or, if desired, the same frequency resources or RAT may be used in multiple power modes. The particular combination of power mode and frequency resources F (as well as the corresponding RAT) that are used by RFFE module 36 may sometimes be collectively referred to herein as the operating mode of RFFE module 36.

Put differently, each operating mode of RFFE module 36 may correspond to a different respective combination of power mode (e.g., one of high power mode HP, mid power mode MP, or low power mode LP), frequency resources F (e.g., frequency band), and/or RAT. Each operating mode may correspond to a different setting of power amplifier 40, mode switching circuitry 60, and RF coupler 62 (e.g., as set using control signals CTRL1 and CTRL2). RFFE module 36 may be placed into the operating mode that optimizes wireless performance and ensures that RFFE module 36 meets the requirements for transmission of each packet in the radio-frequency signals received by RFFE module 36.

If desired, the power mode for each operating mode may be defined by the modulation coding scheme (MCS) rate associated with the operating mode (or the radio-frequency signals to be transmitted while RFFE module 36 is in the corresponding operating mode). For example, a high power mode HP may be assigned to operating modes used when the MCS has a relatively low rate (e.g., 23 dBm), a first mid power mode MP1 may be assigned to operating modes that use MCS11 at a 18 dBm switching point, a second mid power mode MP2 may be defined at 12 dBm for operation at backed off power, a low power mode LP may be defined for 3 dBm and below for CLPC, etc.

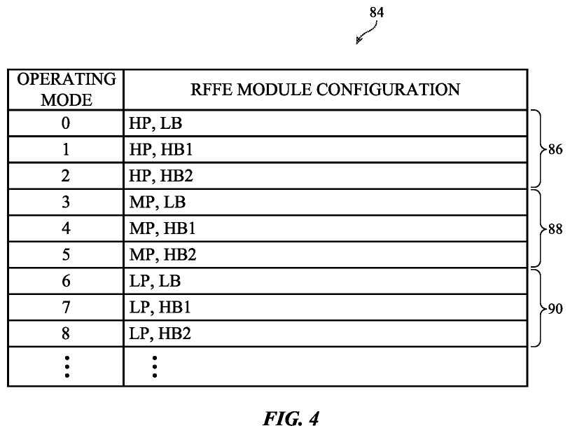

FIG. 4 shows a table 84 of exemplary operating modes for RFFE module 36. The first column of table 84 lists the different operating modes of RFFE module 36. The second column of table 84 lists the power and frequency configuration of RFFE module 36 when placed in the corresponding operating mode (e.g., the operating mode given by the entry of the first column from the same row of table 84). The power and frequency configurations may correspond to different settings for the components of RFFE module 36 (e.g., settings for power amplifier 40 and mode switching circuitry 60 that implement the power configuration and settings for power amplifier 40 and RF coupler 62 that implement the frequency configuration).

Control circuitry 14 (FIG. 1) may identify each operating mode by a different respective digital value of control signal CTRL1. Digital control interface 70 (FIG. 2) may map the digital value of control signal CTRL1 to the corresponding configuration of RFFE module 36 using entries of register 76. Each entry of register 76 may, for example, map digital values of control signal CTRL1 to corresponding values of control signals CTRL2 to be provided to power amplifier 40, mode switching circuitry 60, and RF coupler 62. Different values of control signals CTRL2 may configure power amplifier 40, mode switching circuitry 60, and RF coupler 62 to exhibit different settings or operating characteristics (e.g., to implement the power and frequency configurations of the associated operating mode).

For example, as shown in FIG. 4, RFFE module 36 may have a first set of operating modes 86 in which RFFE module 36 operates in high power mode HP. Each operating mode 86 may correspond to a different respective frequency configuration/band (e.g., a low band LB, a first high band HB1, a second high band HB2, etc.) of the radio-frequency signals to be transmitted by RFFE module 36 (e.g., using the maximum number of active stages in high power mode HP). Each of the frequency bands may belong to a different respective RAT or two or more of the frequency bands may belong to the same RAT. Low band LB, high band HB1, and high band HB2 may, for example, be defined as sub-bands of a 5-7 GHz frequency band (e.g., a Wi-Fi 6E band).

RFFE module 36 may also have a second set of operating modes 88 in which RFFE module 36 operates in mid power mode MP. Each operating mode 88 may correspond to a different respective frequency configuration/band (e.g., low band LB, high band HB1, high band HB2, etc.) of the radio-frequency signals to be transmitted by RFFE module 36 (e.g., using a moderate number of active stages in mid power mode MP).

RFFE module 36 may also have a third set of operating modes 90 in which RFFE module 36 operates in low power mode LP. Each operating mode 90 may correspond to a different respective frequency configuration/band (e.g., low band LB, high band HB1, high band HB2, etc.) of the radio-frequency signals to be transmitted by RFFE module 36 (e.g., using a minimal number of active stages in low power mode LP).

Consider an example in which device 10 needs to transmit a set of one or more packets in radio-frequency signals transmitted using low band LB of a first RAT (e.g., for one or more applications run by an application processor (AP) in control circuitry 14). Control circuitry 14 may place RFFE module 36 into whichever of operating mode 0, operating mode 3, or operating mode 6 would optimize the wireless performance of RFFE module 36 while also meeting the specification requirements of the first RAT and satisfying any regulatory requirements for radio-frequency exposure or absorption.

For example, if a relatively high transmit power level is needed for the radio-frequency signals to be successfully received by a receiving device, control circuitry 14 may place RFFE module 36 in operating mode 0 to place power amplifier 40 in high power mode HP. Power amplifier 40 and mode switching circuitry 60 may be configured (using control signal CTRL2) to activate a maximal number of stages in power amplifier 40. Circuitry in power amplifier 40 and/or RF coupler 62 may be adjusted to optimize the performance of RFFE module 36 in transmitting radio-frequency signals in low band LB.

However, if such a high transmit power level is not necessary for successful receipt of the radio-frequency signals by the receiving device, control circuitry 14 may place RFFE module 36 in operating mode 3 or operating mode 6 (e.g., may reduce the number of active stages in power amplifier 40) to save power, save battery, and/or reduce device temperature. Similarly, if a human body is located nearby the transmitting antenna, control circuitry 14 may place RFFE module 36 in operating mode 3 or operating mode 6 to minimize exposure to radio-frequency energy to ensure compliance with regulatory requirements.

Consider another example in which device 10 needs to transmit a set of one or more packets in radio-frequency signals transmitted using high band HB2 of a second RAT. Control circuitry 14 may place RFFE module 36 into whichever of operating mode 2, operating mode 5, or operating mode 8 would optimize the wireless performance of RFFE module 36 while also meeting the specification requirements of the second RAT and satisfying any regulatory requirements for radio-frequency exposure or absorption.

For example, if a relatively high transmit power level is needed for the radio-frequency signals to be successfully received by a receiving device, control circuitry 14 may place RFFE module 36 in operating mode 2 to place power amplifier 40 in high power mode HP. Power amplifier 40 and mode switching circuitry 60 may be configured (using control signal CTRL2) to activate a maximal number of stages in power amplifier 40. Circuitry in power amplifier 40 and/or RF coupler 62 may be adjusted to optimize the performance of RFFE module 36 in transmitting radio-frequency signals in high band HB2.

However, if such a high transmit power level is not necessary for successful receipt of the radio-frequency signals by the receiving device, control circuitry 14 may place RFFE module 36 in operating mode 5 or operating mode 8 (e.g., may reduce the number of active stages in power amplifier 40) to save power, save battery, and/or reduce device temperature. Similarly, if a human body is located nearby the transmitting antenna, control circuitry 14 may place RFFE module 36 in operating mode 5 or operating mode 8 to minimize exposure to radio-frequency energy to ensure compliance with regulatory requirements.

The example of FIG. 4 is illustrative and non-limiting. RFFE module 36 may include any desired number of operating modes (e.g., for each combination of RAT, radio, frequency band, MCS, etc., and for any desired number of power modes). Control circuitry 14 may switch RFFE module 36 between the different operating modes as needed to ensure each packet of wireless data to be transmitted by RFFE module 36 is transmitted using settings for power amplifier 40, mode switching circuitry 60, and RF coupler 62 that optimize wireless performance at the corresponding frequency while meeting the requirements of the corresponding RAT/radio, minimizing power consumption, and meeting regulatory requirements.

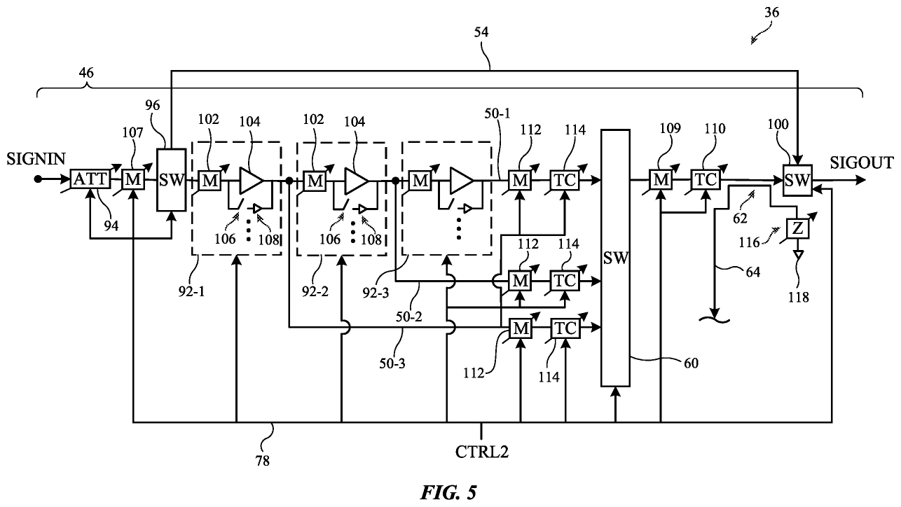

FIG. 5 is a circuit diagram how power amplifier 40, mode switching circuit 60, and RF coupler 62 may include circuitry that is adjusted by control signals CTRL2 to switch RFFE module 36 between operating modes. In the example of FIG. 5, signal ports 42, signal port 52, power detector 38, buffer 66, receive path 56, LNA 58, and digital control interface 70 of FIG. 2 have been omitted for the sake of clarity.

As shown in FIG. 5, RFFE module 36 may include a signal attenuator 94, impedance matching (M) network 107, and bypass switch 96 disposed on transmit path 46. Matching network 107 may be coupled between signal attenuator 94 and bypass switch 96. Signal attenuator 94, matching network 107, and bypass switch 96 may form part of input switching circuitry 44 of FIG. 2, for example. If desired, bypass switch 96 may be coupled between matching network 107 and signal attenuator 94 or input matching network 107 may be distributed across both sides of bypass switch 96.

RFFE module 36 may also include a bypass switch 100 disposed on transmit path 46. Bypass switch 100 may form part of output switching circuitry 48 of FIG. 2, for example. Bypass path 54 may be coupled between bypass switches 96 and 100. Signal attenuator 94 may receive radio-frequency signal SIGIN (e.g., from a corresponding signal port 42 of FIG. 2). Bypass switch 100 may output radio-frequency signal SIGOUT, which is an amplified version of radio-frequency signal SIGIN when bypass path 54 is switched out of use and an un-amplified version of radio-frequency signal SIGIN when bypass path 54 is switched into use.

Power amplifier 40 may be disposed on transmit path 46 between bypass switch 96 and mode switching circuitry 60. Mode switching circuitry 60 may include one or more switches and may sometimes be referred to herein simply as mode switch 60 or mode selection switch 60. An output matching network 109 and a tunable capacitor (TC) 110 may be disposed on transmit path 46 between mode switch 60 and RF coupler 62. RF coupler 62 may have a first terminal or port coupled to feedback path 64 and a second terminal or port coupled to ground 118 (or another reference potential) through adjustable termination impedance 116 (sometimes referred to herein as impedance termination 116).

Power amplifier 40 may have a set of two or more power amplifier stages such as stages 92 coupled in series between bypass switch 96 and mode switch 60. In the example of FIG. 5, power amplifier 40 has three stages 92-1, 92-2, and 92-3. If desired, power amplifier 40 may have more than three stages 92. Stages 92 may sometimes be referred to herein as amplifier stages 92 or power amplifier stages 92.

As shown in FIG. 5, each stage 92 may include a base amplifier 104 and one or more cells 108 of additional amplifiers coupled in parallel on transmit path 46. Each cell 108 may be activated by closing (turning on) a corresponding switch 106 or may be deactivated by opening (turning off) the corresponding switch 106. When a cell 108 is active, the amplifier in that cell may contribute to the amplification of the radio-frequency signal by the corresponding base amplifier 104 (e.g., boosting the gain or power of the amplified signal). Switch 106 may be coupled to the input or the output of the amplifier in the corresponding cell 108. Each stage 92 may also include an input matching network 102 coupled to the input of base amplifier 104 and the cells 108 of that stage 92. Additionally or alternatively, each stage 92 may include an output matching network (not shown) coupled to the output of base amplifier 104 and the cells 108 of that stage 92.

Bypass switch 96 may have a first output coupled to the input of stage 92-1 and may have a second output coupled to bypass path 54. The output of stage 92-1 may be coupled to the input of stage 92-2. The output of each subsequent stage 92 in power amplifier 40 may be coupled to the input of the next stage 92 in power amplifier 40. The output of each stage 92 of power amplifier 40 may be coupled to a different input terminal of mode switch 60 over a different respective signal path 50. For example, the output of stage 92-3 may be coupled to a first input terminal of mode switch 60 over signal path 50-1, the output of stage 92-2 may be coupled to a second input terminal of mode switch 60 over signal path 50-2, the output of stage 92-1 may be coupled to a third input terminal of mode switch 60 over signal path 50-3, etc. Mode switch 60 may have an output terminal coupled to output matching network 109.

Each stage 92 in power amplifier 40 may have a corresponding output matching network 112 and tunable capacitor 114 coupled to its output and disposed on the corresponding signal path 50. Tuning capacitors 114 may be coupled in series between output matching networks 112 and mode switch 60 or vice versa. Matching networks 107, 102, 112, and 109 may each include any desired impedance matching circuitry such as any desired number of capacitors, inductors, and/or resistors coupled together and/or to ground in any desired manner.

One or more of the components in each of the matching networks may be adjustable and/or switchable (e.g., matching networks 107, 102, 112, and 109 may be adjustable impedance matching networks) and may be adjusted/switched (e.g., using control signals CTRL2 from internal control paths 78) to adjust the impedance of the matching networks. For example, the impedance of input matching networks 102 may be adjusted to perform input impedance matching for the active amplifier(s) in the corresponding stage 92 at the frequencies of radio-frequency signal SIGIN. The impedance of output matching networks 112 may be adjusted to perform output impedance matching for the active amplifier(s) in the corresponding stage 92 at the frequencies of radio-frequency signal SIGIN.

Tunable capacitors 114 and 110 may include one or more adjustable capacitors (e.g., banks of switchable capacitors, varactors, etc.) that are coupled together or to ground in series, in parallel, or in any other desired manner. The adjustable capacitors may be adjusted/switched (e.g., using control signals CTRL2 from internal control paths 78) to tune the capacitance of the adjustable capacitors (e.g., to tune the response of power amplifier 40 to the frequencies of radio-frequency signals SIGIN). Termination impedance 116 of RF coupler 62 may include any desired circuitry such as any desired number of capacitors, inductors, and/or resistors coupled between RF coupler 62 and ground 118 in any desired manner. One or more of the components of termination impedance 116 may be adjusted using control signals CTRL2 from internal control paths 78 (e.g., to calibrate RF coupler 62, to switch the RF coupler between reverse and forward signal measurements, to meet the power requirements of the current operating mode, etc.).

Control signals CTRL2 may also be provided to signal attenuator 94, bypass switch 96, bypass switch 100, mode switch 60, and to each of stages 92 over internal control paths 78. Control signals CTRL2 may control signal attenuator 94 to provide a selected amount of attenuation (or no attenuation) to radio-frequency signal SIGIN. Input matching network 107 may perform impedance matching for radio-frequency signal SIGIN. Bypass switch 96 may pass radio-frequency signal SIGIN to power amplifier 40.

Control signals CTRL2 may control mode switch 60 to activate a selected number of stages 92 at a given time (e.g., to place power amplifier 40 in a desired power mode). For example, control signals CTRL2 may place mode switch 60 in a first switch state in which signal path 50-3 (e.g., the third input terminal of the switch) is coupled to the output terminal of mode switch 60 and output matching network 109 at the output of stage 92-1 (e.g., decoupling signal paths 50-2 and 50-1 from output matching network 109), in a second switch state in which signal path 50-2 (e.g., the second input terminal of the switch) is coupled to the output terminal and output matching network 109 around stage 92-3 (e.g., decoupling signal paths 50-1 and 50-3 from output matching network 109), or in a third switch state in which signal path 50-1 (e.g., the first input terminal of the switch) is coupled to the output terminal and output matching network 109 (e.g., decoupling signal paths 50-2 and 50-3 from output matching network 109).

When mode switch 60 is in the first switch state and couples signal path 50-3 to output matching network 109, stage 92-1 is active (enabled) and the later stages 92 in power amplifier 40 (e.g., stages 92-2 and 92-3) are inactive (disabled). Stage 92-1 may amplify radio-frequency signal SIGIN and may pass the amplified radio-frequency signal to mode switch 60 over signal path 50-3 (bypassing stages 92-2 and 92-3). When mode switch 60 is in the second switch state and couples signal path 50-2 to output matching network 109, stage 92-1 and stage 92-2 are active and the later stages 92 in power amplifier 40 (e.g., stage 92-3) is inactive. Stages 92-1 and 92-2 may amplify radio-frequency signal SIGIN and may pass the amplified radio-frequency signal to mode switch 60 over signal path 50-2 (bypassing stage 92-3). When mode switch 60 is in the third switch state and couples signal path 50-1 to output matching network 109, stages 92-1, 92-2, and 92-3 are active. Stages 92-1, 92-2, and 92-3 may amplify radio-frequency signal SIGIN and may pass the amplified radio-frequency signal to mode switch 60 over signal path 50-1. Mode switch 60 may pass the amplified radio-frequency signal to bypass switch 100 via output matching network 109, tunable capacitor 110, and RF coupler 62. Bypass switch 100 may output the amplified radio-frequency signal as radio-frequency signal SIGOUT.

Control signals CTRL2 may control bypass switches 96 and 100 to transmit radio-frequency signal SIGIN over bypass path 54 or over signal path 46. Control signals CTRL2 may also control the active stage(s) 92 of power amplifier 40 to adjust one or more settings of the active stage(s). For example, control circuitry CTRL2 may control the number of active cells 108 in a given stage 92 (e.g., to adjust the overall gain produced by the stage), may adjust one or more bias voltages provided to one or more of the amplifiers in the given stage 92 (e.g., to adjust the overall gain produced by thee stage), and/or may adjust tuning circuitry (e.g., resistors, capacitors, and/or inductors coupled together in any desired manner) within the given stage 92 (e.g., to tune the stage for optimal amplification and transmission at the frequencies of radio-frequency signal SIGIN). Control circuitry CTRL2 may adjust the bias voltage(s) by adjusting a programmable bias circuit in stage 92, for example.

Control signals CTRL2 may also control matching networks 107, 102, 112, and 109, tunable capacitors 110 and 114, mode switch 60, mode switch 60, stages 92, signal attenuator 94, and/or bypass switches 96 and 100 when placing RFFE module 36 in a selected operating mode. Control signals CTRL2 may also adjust matching networks 107, 102, 112, and 109, tunable capacitors 110 and 114, mode switch 60, mode switch 60, stages 92, signal attenuator 94, and/or bypass switches 96 and 100 to switch RFFE module 36 between operating modes.

For example, control signals CTRL2 may control mode switch 60 to place mode switch 60 in the first switch state (e.g., coupling signal path 50-3 to the output terminal and activating stage 92-1) when RFFE module 36 is in an operating mode associated with low power mode LP (e.g., operating modes 90 of FIG. 4). Control signals CTRL2 may control mode switch 60 to place mode switch 60 in the second switch state (e.g., coupling signal path 50-2 to the output terminal and activating stages 92-1 and 92-2) when RFFE module 36 is in an operating mode associated with mid power mode MP (e.g., operating modes 88 of FIG. 4). Control signals CTRL2 may control mode switch 60 to place mode switch 60 in the third switch state (e.g., coupling signal path 50-1 to the output terminal and activating stages 92-1, 92-2, and 92-3) when RFFE module 36 is in an operating mode associated with high power mode HP (e.g., operating modes 86 of FIG. 4). This is illustrative and non-limiting. In general, any desired number of stages 92 may be active in high power mode HP, mid power mode MP, or low power mode LP, and/or the number of active stages in each power mode may depend on the frequency band of radio-frequency signals SIGIN.

Control signals CTRL2 may also control the number of active cells 108 in each of the active stages 92, the bias voltage(s) provided to the amplifier(s) in each of the active stages 92. the impedance of the input matching network 102 in each of the active stages 92, the tunable components in each of the active stages 92, the impedances of output matching networks 112 of each of the active stages 92, the capacitance of the tunable capacitors 114 of each of the active stages 92, the impedance of input matching network 107, the impedance of output matching network 109, and/or the capacitance of tunable capacitor 110 based on the current operating mode of RFFE module 36 (e.g., to place or configure RFFE module 36 in the current operating mode). The bias voltages and/or the number of active cells in each active stage 92 may, for example, be used to place power amplifier 40 in the power mode associated with the current operating mode.

The impedance of input matching network 107, the impedance of output matching network 109, the capacitance of tunable capacitor 110, termination impedance 116, the impedance of the input matching network 102 of each active stage 92, the impedance of the output matching network 112 of each active stage 92, the tunable components in each active stage 92, and/or the capacitance of the tunable capacitator 114 for each active stage 92 may, for example, be selected based on the frequency associated with the current operating mode or the frequency of radio-frequency signal SIGIN (e.g., to optimize the performance of transmit path 46 in transmitting radio-frequency signal SIGIN at its corresponding frequencies).

In this way (e.g., by placing RFFE module 36 into a corresponding operating mode), the power consumed by power amplifier 40 and the tunable components of transmit path 46 may be dynamically adjusted (e.g., for each transmitted packet or group of packets) in a manner that meets the requirements associated with the frequency, RAT, MCS rate, and/or radio of radio-frequency signal SIGIN while maximizing wireless performance, meeting regulatory requirements, minimizing power consumption, minimizing device temperature, and minimizing space consumed on device 10 by power amplifiers. RFFE module 36 may perform signal transmission while meeting wireless performance metric requirements (e.g., EVM requirements) even for transmit data modulation schemes with intensive constellations (e.g., 1 k QAM modulations, 4 k QAM modulations, etc.), across a wide bandwidth (e.g., for Wi-Fi 6E or 7), and across different antenna VSWRs (e.g., as antenna loading changes over time). If desired, a given frequency band may be divided into sub-bands needed to tune power amplifier 40 for each power mode per band. RFFE module 36 may deliver high efficiencies at maximum transmit power levels as well as at backed-off power levels, even when the different RATs shared by power amplifier 40 have different requirements maximum transmit power and transmit power back-off level requirements.

The RF coupler 62 and power detector 38 shared by each of the radios 28 coupled to power amplifier 40 may provide relatively constant detector performance across each of the operating modes of RFFE module 36. RF coupler 62 may, for example, be calibrated (e.g., with a dedicated transmit signal strength indicator (TSSI) calibration) while RFFE module 36 is in each of the operating modes (e.g., to identify corresponding settings for termination impedance 116 to use in each of the operating modes, across each of the frequency bands or sub-bands associated with the operating modes, etc.). The load pull contours of power amplifier 40 may be defined to specify a region with the power amplifier load expected to meet a specific VSWR. Switchable capacitor and/or inductor networks (e.g., tunable components within stages 92, output matching networks 112, input matching networks 102, and/or tunable capacitors 114) may be used to rotate and move the load presented to power amplifier 40 on the Smith chart in different operating modes based on the corresponding EVM requirements of the operating mode (e.g., as given by the RAT associated with the operating mode). If desired, the tunable capacitor settings can be E-fused per operating mode (e.g., per power mode and frequency band). In addition, passive components in power amplifier 40 may be E-fused for each operating mode.

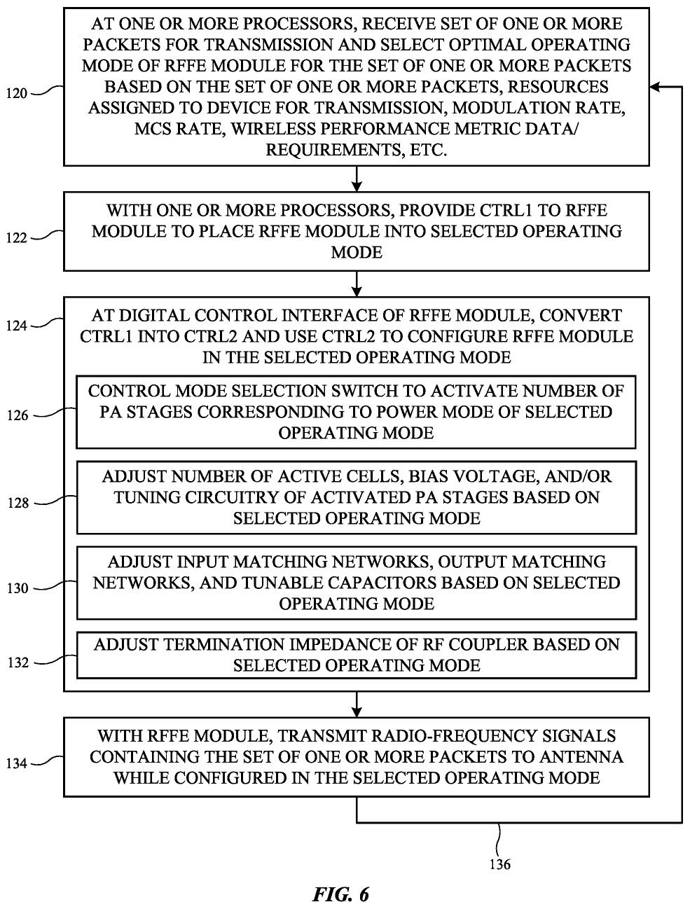

FIG. 6 is a flow chart of illustrative operations that may be performed by RFFE module 36 to transmit radio-frequency signals SIGIN. At operation 120, control circuitry 14 (e.g., baseband circuitry 26 of FIG. 1) may receive or otherwise identify a set of one or more packets of wireless data for transmission (e.g., from the AP). Baseband circuitry 26 may generate baseband signals that include or carry the set of packets. Baseband circuitry 26 may generate the baseband signals using a corresponding modulation type or modulation coding scheme (MCS) (e.g., a quadrature amplitude modulation (QAM) scheme, an amplitude-shift keying (ASK) scheme, a phase-shift keying (PSK) scheme, etc.). The MCS may have a corresponding MCS rate (e.g., the data rate corresponding to the MCS) and may be identified by a corresponding MCS index.

The baseband circuitry may pass the baseband signals to a corresponding radio 28 (e.g., the radio that implements the RAT to be used to transmit the set of packets). The radio may upconvert the baseband signals into a radio-frequency signal using its corresponding RAT, which may be subject to wireless performance requirements (e.g., EVM/SNR requirements) associated with that RAT. Different RATs may have different requirements. Different RATs may also support different modulation schemes, MCS rates, bandwidths, etc. The radio may transmit the radio-frequency signal, which includes or carries the set of packets, to RFFE module 36 (e.g., as radio-frequency signal SIGIN of FIG. 5). The radio may transmit the radio-frequency signal using frequency resources assigned to device 10 (e.g., by the network). The frequency resources (e.g., frequency resources F of FIG. 3) may include a corresponding frequency band and/or sub-band (e.g., a range of Bluetooth frequencies, a range of Wi-Fi 6E frequencies, etc.).

Control circuitry 14 may select (identify) an optimal operating mode for RFFE module 36 to use in transmitting the radio-frequency signal containing the set of packets. Control circuitry 14 may select the optimal operating mode based on content of or information about the set of packets (e.g., the RAT to be used in transmission of the set of packets), resources assigned to device 10 for transmission (e.g., the frequency and/or temporal resources assigned by the network to device 10 for transmission of the radio-frequency signals, the frequency band or sub-band of the radio-frequency signal containing the set of packets, etc.), the MCS or MCS rate used to transmit the set of packets, wireless performance metric requirements (e.g., EVM/SNR requirements) associated with the RAT of the radio 28 that transmits the radio-frequency signal containing the set of packets, wireless performance metric data gathered by device 10, and/or any other desired information. The optimal operating mode may, for example, be the operating mode that causes RFFE module 36 to transmit the radio-frequency signal containing the set of packets while meeting the requirements associated with the frequency resources and/or RAT of the radio-frequency signal containing the set of packets while maximizing wireless performance, and while meeting regulatory requirements and minimizing power consumption.

Consider an example in which the RAT is a WLAN RAT such as Wi-Fi 6E and the radio-frequency signal is in a WLAN frequency band or sub-band. Lower MCS rates may have lower EVM/SNR requirements and may operate at higher power levels whereas higher MCS rates may require high power amplifier linearity and a high EVM floor. An operating mode in which power amplifier 40 is placed in high power mode HP may be defined in which the power amplifier operates for high saturation power but lower EVM floor and lower ICQ. An operating mode in which power amplifier 40 is placed in a first mid power mode MP1 may be defined in which the power amplifier operates for higher EVM requirements at the expense of linearity and power consumption. An operating mode in which power amplifier 40 is placed in a second mid power mode MP2 may be defined in which the power amplifier operates backed off from maximum power but delivers a higher EVM floor. An operating mode in which power amplifier 40 is placed in a third mid power mode MP3 may also be defined in which the power amplifier operates highly backed off from maximum power with scaled saturation power but maintained EVM.

These examples are illustrative and non-limiting and, in general, any operating modes may be defined or selected. If desired, each operating mode may be defined to operated within a specific power range. A threshold RF power may be defined where RFFE module 36 switches between operating modes based on target power and MCS rate. RFFE module 36 may, for example, include a look up table defining when to use each operating mode or power mode (e.g., defining when to switch between operating modes having different power modes). Operating mode selection may be performed on a per-packet or per-group of packets basis.

At operation 122, control circuitry 14 may provide control signal CTRL1 to RFFE module 36 (e.g., at control ports 74 of FIG. 2). The value of control signal CTRL1 may identify or correspond to the selected operating mode.

At operation 124, digital control interface 70 on RFFE module 36 may generate control signal CTRL2 based on the received control signal CTRL1. Control signal CTRL1 may, for example, be transmitted by the control circuitry as an RFFE commend via Reg0. Digital control interface 70 may include logic having a set of registers (e.g., register 76 of FIG. 2) assigned for each operating mode, where each RFFE commend applies all of the component settings required for that operating mode. Digital control interface 70 may use control signal CTRL2 to adjust the components of RFFE module 36 over internal control paths 78 (e.g., as shown in FIG. 5) to place RFFE module 36 into the selected operating mode (e.g., to configure the components of RFFE module 36 using settings that cause the components to implement the operating mode). This setting may occur on a per-packet or per-group of packets basis.

In placing RFFE module 36 in the selected operating mode, RFFE module 36 may perform any desired combination of operations 126-132. Operations 126-132 may be performed concurrently if desired.

At operation 126, control signal CTRL2 may control mode switch 60 to activate a corresponding number of stages 92 (e.g., to implement the power mode of the selected operating mode).

At operation 128, control signal CTRL2 may adjust the number of active cells 108 in the active stage(s) 92, may adjust the bias voltages provided to the active stage(s) 92, and/or may adjust one or more tunable components within the active stage(s) 92. Adjustments to the bias voltage(s), matching network(s), and tunable capacitor(s) may settle in 1 us or less based on packet timing requirements, for example.

At operation 130, control signal CTRL2 may adjust input matching network 107, output matching network 109, tunable capacitor 110, the input matching network 102 in the active stage(s) 92, the output impedance matching network 112 of the active stage(s) 92, and/or the tunable capacitor 114 of the active stage(s) 92.

At operation 132, control signal CTRL2 may adjust termination impedance 116 of RF coupler 62. The settings or adjustments performed at operations 126-132 may serve to place or configure RFFE module 36 in the selected operating mode.

At operation 134, RFFE module 36 may transmit the radio-frequency signal containing the set of packets to the antenna(s) 34 coupled to signal port 52 while RFFE module 36 is configured in the selected operating mode. The active stage(s) 92 of power amplifier 40 may amplify the transmitted radio-frequency signal in a manner that meets the requirements of the RAT, frequency resources, MCS rate, etc. of the radio-frequency signal while minimizing power consumption, optimizing wireless performance, and meeting regulatory requirements. Antenna(s) 34 may transmit the radio-frequency signal to external communications equipment. Processing may loop back to operation 120 via path 136 and control circuitry 14 may reconfigure the operating mode of RFFE module 36 for the next set of one or more packets (e.g., in a stream of packets received from the AP).

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The methods and operations described above in connection with FIGS. 1-4 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry 18 of FIG. 1, etc.). The processing circuitry may include microprocessors, central processing units (CPUs), application-specific integrated circuits with processing circuitry, or other processing circuitry.

The foregoing is merely illustrative and various modifications can be made to the described embodiments. The foregoing embodiments may be implemented individually or in any combination.

What is claimed is:

1. An electronic device comprising:
a transmission line configured to convey a radio-frequency signal;
a switch disposed on the transmission line; and
a power amplifier disposed on the transmission line and configured to amplify the radio-frequency signal, the power amplifier including
a first amplifier stage having an input and an output,
a first signal path that couples the output of the first amplifier stage to a first input terminal of the switch,
a second amplifier stage having an output coupled to the input of the first amplifier stage, and
a second signal path that couples the output of the first amplifier stage to a second input terminal of the switch around the first amplifier stage.

2. The electronic device of claim 1, the power amplifier further comprising:
a third amplifier stage having an output coupled to an input of the second amplifier stage; and
a third signal path that couples the output of the third amplifier stage to a third input terminal of the switch around the first amplifier stage and the second amplifier stage.

3. The electronic device of claim 2, wherein the switch has an output terminal, a first state in which the output terminal is coupled to the first input terminal, a second state in which the output terminal is coupled to the second input terminal, and a third state in which the output terminal is coupled to the third input terminal.

4. The electronic device of claim 3, further comprising one or more processors configured adjust the switch based on a modulation coding scheme (MCS) and a power of the radio-frequency signal.

5. The electronic device of claim 3, further comprising one or more processors configured adjust the switch based on a radio access technology (RAT) of the radio-frequency signal.

6. The electronic device of claim 3, further comprising one or more processors configured adjust the switch based on a frequency of the radio-frequency signal.

7. The electronic device of claim 1, further comprising:
a first radio communicably coupled to an input of the power amplifier, the first radio being configured to transmit the radio-frequency signal using a first radio access technology (RAT); and
a second radio communicably coupled to the input of the power amplifier, the second radio being configured to transmit the radio-frequency signal using a second RAT that is different from the first RAT.

8. The electronic device of claim 7, further comprising:
an antenna communicably coupled to an output terminal of the switch over the transmission line, wherein the switch is configured to couple the first amplifier stage and the second amplifier stage to the antenna concurrent with the first radio transmitting the radio-frequency signal and is configured to couple the second amplifier stage but not the first amplifier stage to the antenna concurrent with the second radio transmitting the radio-frequency signal.

9. The electronic device of claim 8, further comprising:
a radio-frequency coupler disposed on the transmission line between the switch and the antenna; and
a power detector coupled to the radio-frequency coupler, the radio-frequency coupler being configured to couple a portion of the radio-frequency signal off the transmission line and towards the power detector.

10. The electronic device of claim 1, further comprising:
a bypass switch disposed on the transmission line;
a first adjustable impedance matching network disposed on the transmission line and coupled to an input of the bypass switch;
a second adjustable impedance matching network disposed on the transmission line and coupled between an output of the bypass switch and the second amplifier stage;
a third adjustable impedance matching network disposed on the first signal path between the first input port of the switch and the output of the first amplifier stage; and
a fourth adjustable impedance matching network disposed on the second signal path between the second input port of the switch and the output of the second amplifier stage;
a first set of one or more amplifiers in the first amplifier stage; and
a fifth adjustable impedance matching network coupled between the output of the second amplifier stage and the first set of one or more amplifiers in the first amplifier stage.

11. The electronic device of claim 10, further comprising:
a second set of one or more amplifiers in the second amplifier stage; and
a sixth adjustable impedance matching network coupled to the second set of one or more amplifiers in the second amplifier stage, the second set of one or more amplifiers being coupled between the sixth adjustable impedance matching network and the fifth adjustable impedance matching network.

12. The electronic device of claim 1, further comprising:
a first tunable capacitor disposed on the first signal path between the first input port of the switch and the output of the first amplifier stage;
a second tunable capacitor disposed on the second signal path between the second input port of the switch and the output of the second amplifier stage; and
a third tunable capacitor disposed on the transmission line, the switch being coupled between the third tunable capacitor and the power amplifier.

13. The electronic device of claim 1, further comprising:
an antenna communicably coupled to an output terminal of the switch over the transmission line;
an impedance matching network disposed on the transmission line between the output terminal of the switch and the antenna;
a radio-frequency coupler disposed on the transmission line between the impedance matching network and the antenna;
a first bypass switch disposed on the transmission line, the first bypass switch having an output communicably coupled to an input of the second amplifier stage;
a second bypass switch disposed on the transmission line between the radio-frequency coupled and the antenna; and
a bypass path coupled between the first bypass switch and the second bypass switch around the power amplifier.

14. An electronic device comprising:
an antenna;
a first radio configured to generate a first radio-frequency signal using a first radio access technology (RAT);
a second radio configured to generate a second radio-frequency signal using a second RAT different from the first RAT;
a substrate separate from the first radio and the second radio;
a transmission line on the substrate that communicably couples the first radio and the second radio to the antenna; and
a power amplifier on the substrate and disposed on the transmission line, wherein the power amplifier has power amplifier stages, the power amplifier is configured to transmit the first radio-frequency signal using a set of the power amplifier stages, and the power amplifier is configured to transmit the second radio-frequency signal using a subset of the set of the power amplifier stages.

15. The electronic device of claim 14, further comprising:
a radio-frequency coupler on the substrate and disposed on the transmission line, the radio-frequency coupler being coupled between the power amplifier and the antenna.

16. The electronic device of claim 15, further comprising:
a switch on the substrate and disposed on the transmission line, wherein the switch is coupled between the radio-frequency coupler and the power amplifier, the switch has input terminals each coupled to an output of a different respective amplifier stage in the power amplifier, and the switch has an output terminal communicably coupled to the antenna; and
output impedance matching networks on the substrate and coupled between the outputs of the amplifier stages and the input terminals of the switch, wherein the switch has a first state and the output impedance matching networks have first settings concurrent with transmission of the first radio-frequency signal by the power amplifier, and the switch has a second state and the output impedance matching networks have second settings concurrent with transmission of the second radio-frequency signal by the power amplifier.

17. The electronic device of claim 16, further comprising:
a digital interface on the substrate and configured to receive a digital control signal from one or more processors; and
control paths on the substrate that couple the digital interface to the switch, the radio-frequency coupler, the power amplifier stages, and the output impedance matching networks, the digital interface being configured to adjust the switch, the radio-frequency coupler, the power amplifier stages, and the output impedance matching networks over the control paths based on the digital control signal.

18. A method of operating wireless circuitry to transmit a radio-frequency signal, the method comprising:
transmitting radio-frequency signals using one or more radios;
amplifying the radio-frequency signals using a set of power amplifier stages coupled in series between the one or more radios and an antenna; and
adjusting, using one or more processors, a number of power amplifier stages in the set of power amplifier stages based on a radio access technology (RAT) of the radio-frequency signals.

19. The method of claim 18, wherein the radio-frequency signals contain a data packet, the method further comprising:
adjusting, using the one or more processors, the number of power amplifier stages in the set of power amplifier stages based on a modulation coding scheme (MCS) of the data packet;
adjusting, using the one or more processors, a number of active cells in each of the power amplifier stages of the set of power amplifier stages based on the MCS of the data packet;
adjusting, using the one or more processors, a bias voltage provided to each of the power amplifier stages of the set of power amplifier stages based on the MCS of the data packet; and
adjusting, using the one or more processors, output impedance matching networks coupled to outputs of each of the power amplifier stages in the set of power amplifier stages based on a frequency of the radio-frequency signals.

20. The method of claim 18, wherein adjusting the number of power amplifier stages in the set of power amplifier stages comprises adjusting the number of power amplifier stages in the set of power amplifier stages on a packet-by-packet basis.
